(19) United States
(12) Patent Application Publication
(10) Pub. No.: US 2017/0358695 A1
(43) Pub. Date: Dec. 14, 2017

(54) TEXTURED STRUCTURE OF CRYSTALLINE SILICON SOLAR CELL AND PREPARATION METHOD THEREOF

(71) Applicant: CSI CELLS CO., LTD, Suzhou, Jiangsu (CN)

(72) Inventors: Shuai ZOU, Suzhou (CN); Xusheng WANG, Suzhou (CN); Guoqiang XING, Suzhou (CN)

(73) Assignee: CSI Cells Co., Ltd, Suzhou, Jiangsu (CN)

(21) Appl. No.: 15/514,408

(22) PCT Filed: Dec. 13, 2015
(86) PCT No.: PCT/CN2015/100123

§ 371 Date: Mar. 24, 2017

(30) Foreign Application Priority Data
Jul. 9, 2015 (CN) 201510398065.0

(51) Int. Cl. H01L 31/0236; H01L 31/18; C01B 33/02; H01L 21/308; H01L 21/306; H01L 31/054

(52) U.S. Cl. CPC H01L 31/02363; H01L 21/308; H01L 21/30604; H01L 31/1804; C01B 33/02; H01L 31/054; C01P 2004/03

(57) ABSTRACT

A textured structure of a crystalline silicon solar cell that is mainly constructed by a plurality of micro-structures similar to inverted pyramids; the lower part of the micro-structure similar to the inverted pyramid is an inverted pyramidal structure, and the upper part thereof is an inverted circular truncated conical structure; and the top of the micro-structure similar to the inverted pyramid is selected from one or more of a circle, an oval, or a closed figure enclosed by multiple curves. Experiments prove that the conversion efficiency of a cell piece may be improved by 0.25-0.4%, thereby obtaining unexpected effects.

### TECHNICAL FIELD

The present invention relates to the field of solar cell technologies, and in particular to a textured structure of crystalline silicon solar cell and a preparation method thereof.

### BACKGROUND

Along with the broad application of solar cell assemblies, photovoltaic power generation occupies an increasingly important percentage of new energy resources, and is developed rapidly. In current among commercial solar cell products, crystalline silicon (mono-crystalline and polycrystalline) solar cells occupy the maximum market share, and maintains more than 85% of the market share.

Currently, in the production process of the solar cell, a textured structure of the surface of a silicon wafer can effectively reduce the surface reflectivity of the solar cell, which is one of the most important factors affecting the photoelectric conversion efficiency of the solar cell. In order to obtain a better antireflection effect, many methods are tried to obtain a good textured structure on the surface of a crystalline silicon solar cell, and common methods include a mechanical grooving method, a laser etching method, a reaction ion etching (RIE) method, a chemical corrosion method (that is, wet corrosion), and the like. The mechanical grooving method can obtain a low surface reflectivity, but this method causes severe mechanical damages on the surface of the silicon wafer, and the yield thereof is relatively low; therefore, this method is rarely used in industrial production. The laser etching method refers to manufacturing different groove patterns by using lasers, stripe-shaped and inverted pyramid-shaped surfaces have all been manufactured, and the reflectivity thereof may be as low as 8.3%; however, the efficiency of a cell manufactured thereby is low, so this method cannot be effectively used in production. The RIE method may use different templates for etching, the etching is generally dry etching, in which so-called “black silicon” structures are formed on the surface of a silicon wafer, and the reflectivity may be as low as 7.9%, or may even reach 4%; however, this method is rarely used in industrial production due to expensive devices and high production cost. The chemical corrosion method has characteristics such as a simple process, low cost, high quality, and compatibility with the conventional process, and becomes the most used method in the existing industry.

Currently, a textured structure of a crystalline silicon solar cell manufactured by using the wet corrosion is generally micron-sized. The currently common method further reduces the surface reflectivity thereof. The patent application No. WO2014120830 (A1) discloses a preparation method of a crystalline silicon nano-sized texture, in which control on the shape of the nano-sized texture is implemented by using annealing; however, this method has a complicated process, and inconvenient for industrial production.

Therefore, it is obviously one of the research and development directions in the field to develop a new textured structure of a crystalline silicon solar cell, to further reduce the surface reflectivity of the textured structure, to improve the conversion efficiency of a cell piece, and to further simplify the processing process.

### SUMMARY

An objective of the present invention is to provide a textured structure of crystalline silicon solar cell and a preparation method thereof.

To achieve the above inventive objective, a technical solution adopted in the present invention is: a textured structure of a crystalline silicon solar cell, where the textured structure is mainly constructed by a plurality of micro-structures similar to inverted pyramids;

the lower part of the micro-structure similar to the inverted pyramid is an inverted pyramidal structure and the upper part thereof is an inverted circular truncated conical structure; and

the top of the micro-structure similar to the inverted pyramid is selected from one or more of a circle, an oval, or a closed figure enclosed by multiple curves.

In the above text, the top of the micro-structure similar to the inverted pyramid is selected from one or more of a circle, an oval, or a closed figure enclosed by multiple curves, where the closed figured enclosed by multiple curves at least includes 3 curves, definitely, and it may also be enclosed by more curves, preferably 5-8 curves. The top of the inverted conical structure is the bottom of the cone, and since it is inverted, the bottom of the cone becomes the top of the micro-structure.

The textured structure has a plurality of micro-structures similar to inverted pyramids, and these structures similar to inverted pyramids may be independently distributed on the surface of the silicon wafer, and may be partially overlapped, or multiple inverted conical structures are partially overlapped.

The depth of the micro-structures similar to inverted pyramids is 100-900 nm. The average reflectivity of the textured structure is 2-20%, and preferably 5-15%. (Here, it is suggested that the range is smaller and jumps out of the existing range).

The distribution density of the micro-structures on the textured is 10⁹-10¹² pieces/cm².

In the above technical solution, the size of the micro-structure similar to the inverted pyramid is 100-900 nm.

In the above technical solution, the textured structure further has a plurality of pyramid micro-structures. That is, the textured structure is formed by the micro-structures similar to inverted pyramids and the pyramid micro-structures.

The present invention also claims for protection on a preparation method of a textured structure of a crystalline silicon solar cell, including the following steps:

(1) immersing a silicon wafer in a solution containing metal ions, so that a layer of metal nano-particles is coated on the surface of the silicon wafer;

the concentration of the metal ions in the solution being less than or equal to 1E⁻³ mol/L or the concentration of the metal ions in the solution being greater than 1E⁻³ mol/L while the concentration of HF being less than or equal to 1E⁻² mol/L;

(2) corroding the surface of the silicon wafer by using a first chemical corrosive liquid, so as to form nanowires or porous silicon structures, the temperature being 25-90° C., and the time being 2-10 min;

the first chemical corrosive liquid being a mixed solution of HF and an oxidant, where the concentration of the HF is 1-15 mol/L, and the concentration of the oxidant is 0.05-0.5 mol/L;

the oxidant being selected from H₂O₂, HNO₃, or H₂CrO₄;

(3) placing the silicon wafer in a second chemical corrosive liquid to perform corrective corrosion, so that the nanowires or porous silicon structures are formed into nano-deep hole structures;

the second chemical corrosive liquid being a mixed solution of an oxidant and the HF acid, the concentrations of the HF and the oxidant being respectively 0.05-0.5 mol/L and 1-10 mol/L, the reaction time being 10-1000 seconds, and the reaction temperature being 5-45° C.;

(4) placing the silicon wafer in a third chemical corrosive liquid to perform corrective corrosion, so that the nano-deep hole structures are formed into micro-structures similar to inverted pyramids;

the lower part of the micro-structure similar to the inverted pyramid being an inverted pyramidal structure and the upper part thereof being an inverted circular truncated conical structure; the top of the micro-structure similar to the inverted pyramid being selected from one or more of a circle, an oval, or a closed figure enclosed by multiple curves;

the third chemical corrosive liquid being an alkali liquor;

the concentration of the alkali liquor being 0.001-0.1 mol/L, the reaction time being 10-1000 seconds, and the reaction temperature being 5-85° C. The alkali liquor is selected from one of the following solutions: an NaOH solution, a KOH solution, and a tetramethylammonium hydroxide solution.

In the foregoing, the metal ions may be selected from metal ions of the prior art, for example, one or more of gold, silver, copper, and nickel.

The concentration of the metal ions in the solution of the step (1) is less than or equal to 1E⁻³ mol/L or the concentration of the metal ions in the solution is greater than 1E⁻³ mol/L and the concentration of HF is less than or equal to 1E⁻² mol/L; therefore, the gap between two adjacent metal nano-particles is greater than twice of the size of the nano-particle. As a result, the micro-structure similar to the inverted pyramid is formed.

In the foregoing, in the step (1), the immersing time is 10-1000 seconds, and the solution temperature is 5-85° C. The corroding time in the step (3) is 30-3000 seconds, and the reaction temperature is 5-45° C. The textured structure formed in the above method has a plurality of micro-structures similar to inverted pyramids, and these micro-structures may be independently distributed on the surface of the silicon wafer, and may be partially overlapped, or multiple inverted conical structures are partially overlapped.

The texturizing method belongs to a two-step texturizing method.

In the above technical solution, the solution containing metal ions in the step (1) further includes HF.

In the above technical solution, after the step (4), the method further includes a step of removing the metal ions, specifically:

metal particles are removed respectively by washing the silicon wafer using a first cleaner, a second cleaner, and a deionized water;

where the first cleaner is a nitric acid solution with mass percentage of 27-69%, the cleaning time is 60-1200 seconds, and the cleaning temperature is 5-85° C.; and

the second cleaner is a hydrofluoric acid solution with mass percentage of 1-10%, the cleaning time is 60-600 seconds, and the cleaning temperature is 5-45° C.

Another corresponding technical solution, a preparation method of a textured structure of a crystalline silicon solar cell includes the following steps:

(1) placing a silicon wafer into a hydrofluoric acid solution containing an oxidant and a metal salt, so as to form nanowires or porous silicon structures, the temperature being 25-90° C., and the time being 2-10 min;

the concentration of the metal ions in the solution being less than or equal to 1E⁻³ mol/L or the concentration of the metal ions in the solution being greater than 1E⁻³ mol/L while the concentration of HF being less than or equal to 1E⁻² mol/L;

(2) placing the silicon wafer in a first chemical corrosive liquid to perform corrective corrosion, so that the nanowires or porous silicon structures are formed into nano-deep hole structures;

the first chemical corrosive liquid being a mixed solution of an oxidant and the HF acid, the concentrations of the HF and the oxidant being respectively 0.05-0.5 mol/L and 1-10 mol/L, the reaction time being 10-1000 seconds, and the reaction temperature being 5-45° C.;

(3) placing the silicon wafer in a second chemical corrosive liquid to perform corrective corrosion, so that the nano-deep hole structures are formed into micro-structures similar to inverted pyramids;

the lower part of the micro-structure similar to the inverted pyramid being an inverted pyramidal structure, and the upper part thereof being an inverted circular truncated conical structure; the top of the micro-structure similar to the inverted pyramid being selected from one or more of a circle, an oval, or a closed figure enclosed by multiple curves;

the second chemical corrosive liquid being an alkali liquor;

the concentration of the alkali liquor being 0.001-0.1 mol/L, the reaction time being 10-1000 seconds, and the reaction temperature being 5-85° C.

The texturizing method belongs to a one-step texturizing method. The tetramethylammonium hydroxide solution is also referred to as a TMAH solution.

The metal ions may be selected from metal ions of the prior art, for example, one or more of gold, silver, copper, and nickel.

In the above technical solution, before or after the correction step, the method further includes a step of removing the metal ions, specifically:

metal particles are removed respectively by washing the silicon wafer using a first cleaner, a second cleaner, and a deionized water;

where the first cleaner is a nitric acid solution with mass percentage of 27-69%, the cleaning time is 60-1200 seconds, and the cleaning temperature is 5-85° C.; and

the second cleaner is a hydrofluoric acid solution with mass percentage of 1-10%, the cleaning time is 60-600 seconds, and the cleaning temperature is 5-45° C.

Corresponding to the micro-structures similar to inverted pyramids, another technical solution of the present invention is: a textured structure of a crystalline silicon solar cell, where the textured structure is mainly constructed by a plurality of pyramid micro-structures;

the size of the pyramid is 100-500 nm.

In the above technical solution, the textured structure further has a plurality of micro-structures similar to inverted pyramids;

the lower part of the micro-structure similar to the inverted pyramid is an inverted pyramidal structure, and the upper part thereof is an inverted circular truncated conical structure; and

the top of the micro-structure similar to the inverted pyramid is selected from one or more of a circle, an oval, or a closed figure enclosed by multiple curves.

The above solution is a combination of two kinds of micro-structures. The pyramid micro-structures are dominative.

The preparation method of a textured structure of a crystalline silicon solar cell includes the following steps:

(1) immersing a silicon wafer in a solution containing metal ions, so that a layer of metal nano-particles is coated on the surface of the silicon wafer;

the concentration of the metal ions in the solution being greater than 1E⁻³ mol/L and the concentration of HF being greater than 1E⁻² mol/L;

(2) corroding the surface of the silicon wafer by using a first chemical corrosive liquid, so as to form nanowires or porous silicon structures, the temperature being 25-90° C., and the time being 2-10 min;

the first chemical corrosive liquid being a mixed solution of HF and an oxidant, where the concentration of the HF is 1-15 mol/L, and the concentration of the oxidant is 0.05-0.5 mol/L;

(3) placing the silicon wafer in a second chemical corrosive liquid to perform corrective corrosion, so that the nanowires or porous silicon structures are formed into pyramid micro-structures;

the second chemical corrosive liquid being an alkali liquor;

the concentration of the alkali liquor being 0.001-0.1 mol/L, the reaction time being 10-1000 seconds, and the reaction temperature being 5-85° C.

In the above text, the concentration of the metal ions in the solution of the step (1) is greater than 1E⁻³ mol/L, and the concentration of HF is greater than 1E⁻² mol/L; therefore, the gap between two adjacent metal nano-particles is less than twice of the size of the nano-particle, so as to form the pyramid micro-structure.

The texturizing method belongs to a two-step texturizing method.

The metal ions may be selected from metal ions of the prior art, for example, one or more of gold, silver, copper, and nickel.

In the above technical solution, before or after the correction step, the method further includes a step of removing the metal ions, in which metal particles are removed respectively by washing the silicon wafer using a first cleaner, a second cleaner, and a deionized water;

where, the first cleaner is a nitric acid solution with mass percentage of 27-69%, the cleaning time is 60-1200 seconds, and the cleaning temperature is 5-85° C.; and

the second cleaner is a hydrofluoric acid solution with mass percentage of 1-10%/o, the cleaning time is 60-600 seconds, and the cleaning temperature is 5-45° C.

In the above technical solution, the solution containing metal ions in the step (1) further includes HF.

Another corresponding technical solution, a preparation method of a textured structure of a crystalline silicon solar cell includes the following steps:

(1) placing a silicon wafer into a hydrofluoric acid solution containing an oxidant and a metal salt, so as to form nanowires or porous silicon structures; the temperature being 25-90° C., and the time being 2-10 min;

the concentration of the metal ions in the solution being greater than 1E⁻³ mol/L, and the concentration of HF being greater than 1E⁻² mol/L;

(2) placing the silicon wafer in a first chemical corrosive liquid to perform corrective corrosion, so that the nanowires or porous silicon structures are formed into pyramid micro-structures;

the first chemical corrosive liquid being an alkali liquor;

the concentration of the alkali liquor being 0.001-0.1 mol/L, the reaction time being 10-1000 seconds, and the reaction temperature being 5-85° C.

In the above technical solution, before or after the correction step, the method further includes a step of removing the metal ions, in which metal particles are removed respectively by washing the silicon wafer using a first cleaner, a second cleaner and a deionized water,

where the first cleaner is a nitric acid solution with mass percentage of 27-69%, the cleaning time is 60-1200 seconds, and the cleaning temperature is 5-85° C.; and

the second cleaner is a hydrofluoric acid solution with mass percentage of 1-10%/o, the cleaning time is 60-600 seconds, and the cleaning temperature is 5-45° C.

By using the technical solution, compared with the prior art, the present invention has the following advantages:

1. The present invention discloses a new textured structure of a crystalline silicon solar cell, structures similar to inverted pyramids and pyramid structures tightly and uniformly distributed are formed on the surface of a silicon wafer, and the pyramidal structures are all nano-sized. Experiments prove that: the textured structure of the present invention can effectively reduce the reflectivity of the front surface, so that the reflectivity is maximally reduced to 2%. Moreover, compared with the textured structure disclosed in the patent application No. WO2014120830 (A1), the conversion efficiency of a cell piece of the present invention may be improved by 0.25-0.4%, thereby obtaining unexpected effects.

2. A method for controlling nano texture shapes disclosed in the present invention is applicable to all nano textures formed by metal catalytic etching, and pyramid shapes may be simply controlled by using concentrations of solutions, without the need of using annealing to control the shape of the nano texture as described in WO2014120830 (A1); therefore, the process is simple, and is more applicable to industrial production.

3. The present invention forms a nano texture by using chemical corrosion, without the need of mask etching; therefore, the operation process is simple, is well-compatible with the conventional industrial production process, can be quickly implanted to the industrial production, and is suitable for promotion and application.

### DESCRIPTION OF THE DRAWINGS

FIG. 1 is an SEM scanning diagram of a texture of a polycrystalline silicon wafer according to Embodiment 1 of the present invention;

FIG. 2 is an SEM scanning diagram of a texture of a polycrystalline silicon wafer according to Embodiment 2 of the present invention;

FIG. 3 is a schematic diagram of a forming principle of a texture of a polycrystalline silicon wafer according to Embodiment 1 of the present invention; and

FIG. 4 is a schematic diagram of a forming principle of a texture of a polycrystalline silicon wafer according to Embodiment 2 of the present invention.

### DETAILED DESCRIPTION

The present invention is further described through embodiments.

### Embodiment 1

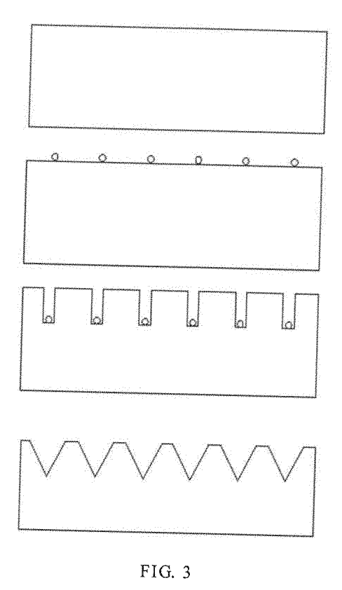

Referring to FIG. 3, a preparation method of a textured structure of a polycrystalline silicon solar cell includes the following steps:

(1) cleaning a silicon wafer to remove a damaged surface layer;

(2) placing the silicon wafer in a chemical corrosive liquid containing metal ions, so as to form nanowires or porous silicon structures on the surface of the silicon wafer, the temperature being 30° C., and the time being 2 min;

the metal ions being selected from silver ions;

the chemical corrosive liquid being selected from a mixed solution of HF and H₂O₂;

where the concentration of the HF is 10 mol/L, and the concentration of the H₂O₂ is 0.4 mol/L;

(3) placing the silicon wafer in a first chemical corrosive liquid to perform corrective corrosion, so that the nanowires or porous silicon structures are formed into nano-deep hole structures;

the first chemical corrosive liquid being a mixed solution of HNO₃ and HF acid, the concentrations of the HF and the HNO₃ being respectively 0.5 mol/L and 10 mol/L, the reaction time being 20 seconds, and the reaction temperature being the room temperature;

(4) placing the silicon wafer in a second chemical corrosive liquid to perform corrective corrosion, so that the nano-deep hole structures are formed into nano-sized micro-structures similar to inverted pyramids;

the lower part of the micro-structure similar to the inverted pyramid being an inverted pyramidal structure, and the upper part thereof being an inverted circular truncated conical structure; the top of the micro-structure similar to the inverted pyramid being selected from one or more of a circle, an oval, or a closed figure enclosed by multiple curves;

the second chemical corrosive liquid being selected from a tetramethylammonium hydroxide solution, the concentration thereof being 0.1 mol/L, the reaction time being 100 seconds, and the reaction temperature being the room temperature;

(5) cleaning and spin-drying, so as to form the textured structure of the crystalline silicon solar cell.

The concentration of the metal ions in the step (2) is 5E⁻⁴ mol/L.

The cleaning in the step (5) specifically includes that:

metal particles are removed respectively by washing the silicon wafer using a first cleaner, a second cleaner, and a deionized water;

where the first cleaner is a nitric acid solution with mass percentage of 69%, the cleaning time is 1200 seconds, and the cleaning temperature is the room temperature; and

the second cleaner is a hydrofluoric acid solution with mass percentage of 10%, the cleaning time is 600 seconds, and the cleaning temperature is the room temperature.

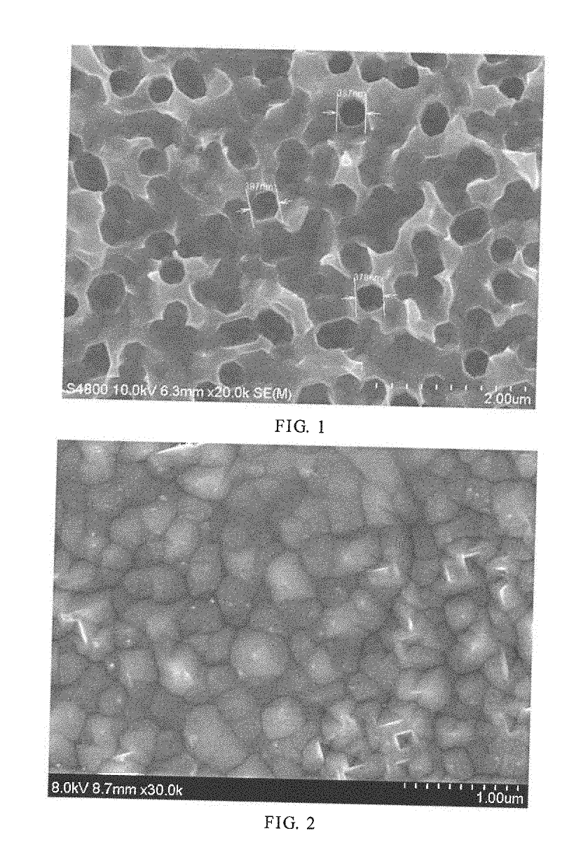

The SEM scanning diagram of the obtained texture of the polycrystalline silicon wafer is shown in FIG. 1, nano-sized micro-structures similar to inverted pyramids in the size of about 400 nm are formed. The lower part of the micro-structure similar to the inverted pyramid is an inverted pyramidal structure, and the upper part thereof is an inverted circular truncated conical structure; the top of the micro-structure similar to the inverted pyramid being selected from one or more of a circle, an oval, or a closed figure enclosed by multiple curves.

### Embodiment 2

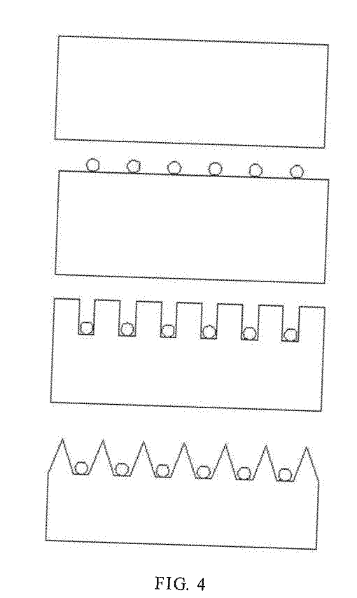

Referring to FIG. 4, a preparation method of a textured structure of a polycrystalline silicon solar cell includes the following steps:

(1) cleaning a silicon wafer to remove a damaged surface layer;

(2) placing the silicon wafer in a chemical corrosive liquid containing metal ions, so as to form nanowires or porous silicon structures on the surface of the silicon wafer; the temperature being 30° C., and the time being 2 min;

the metal ions being selected from silver ions;

the chemical corrosive liquid being selected from a mixed solution of HF and H₂O₂;

where the concentration of the HF is 10 mol/L, and the concentration of the H₂O₂ is 0.4 mol/L;

(3) placing the silicon wafer in a first chemical corrosive liquid to perform corrective corrosion, so that the nanowires or porous silicon structures are formed into nano-deep hole structures;

the first chemical corrosive liquid being a mixed solution of HNO₃ and HF acid, the concentrations of the HF and the HNO₃ being respectively 0.01 mol/L and 10 mol/L, the reaction time being 10 seconds, and the reaction temperature being the room temperature;

(4) placing the silicon wafer in a second chemical corrosive liquid to perform corrective corrosion, so that the nano-deep hole structures are formed into pyramid micro-structures;

the second chemical corrosive liquid being selected from a tetramethylammonium hydroxide solution, the concentration thereof being 0.01 mol/L, the reaction time being 60 seconds, and the reaction temperature being 45° C.;

(5) cleaning and spin-drying, so as to form the textured structure of the crystalline silicon solar cell.

The concentration of the metal ions in the step (2) is 0.1 mol/L.

The cleaning in the step (5) specifically includes that:

metal particles are removed respectively by washing the silicon wafer using a first cleaner, a second cleaner, and a deionized water;

where the first cleaner is a nitric acid solution with mass percentage of 69%, the cleaning time is 1200 seconds, and the cleaning temperature is 80° C.; and

the second cleaner is a hydrofluoric acid solution with mass percentage of 10%, the cleaning time is 600 seconds, and the cleaning temperature is 40° C.

The SEM scanning diagram of the obtained textured of the polycrystalline silicon wafer is shown in FIG. 2, and nano-sized pyramid micro-structures in the size of about 400 nm are formed.

Comparison 1

A nano textured structure is prepared according to the method disclosed in the patent application No. WO2014120830(A1) by using raw materials the same as those in the embodiments.

Comparison results of conversion efficiencies of cell pieces manufactured according to the prior art are shown in the following.

| | Uoc (mV) | Jsc (mA/cm²) | FF (%) | EFF |
|---|---|---|---|---|
| Comparison 1 | 637.7 | 36.05 | 79.30 | 18.23% |
| Embodiment 1 | 638.9 | 36.49 | 79.90 | 18.63% |
| Embodiment 2 | 637.0 | 36.61 | 79.25 | 18.48% |

It can be seen that, compared with the textured structure (comparison) disclosed in the patent application No. WO2014120830(A1), the conversion efficiency of the cell piece of the present invention may be improved by about 0.25-0.4%, thereby achieving unexpected effects.

1. A textured structure of a crystalline silicon solar cell, wherein the textured structure is mainly constructed by a plurality of micro-structures similar to inverted pyramids;
the lower part of the micro-structure similar to the inverted pyramid is an inverted pyramidal structure, and the upper part thereof is an inverted circular truncated conical structure; and
the top of the micro-structure similar to the inverted pyramid is selected from one or more of a circle, an oval, or a closed figure enclosed by multiple curves.

2. The textured structure of a crystalline silicon solar cell according to claim 1, wherein the size of the micro-structure similar to the inverted pyramid is 100-900 nm.

3. The textured structure of a crystalline silicon solar cell according to claim 1, wherein the textured structure further comprises a plurality of pyramid micro-structures.

4. A preparation method of a textured structure of a crystalline silicon solar cell, comprising the following steps:
(1) immersing a silicon wafer in a solution containing metal ions, so that a layer of metal nano-particles is coated on the surface of the silicon wafer;
the concentration of the metal ions in the solution being less than or equal to 1E⁻³ mol/L or the concentration of the metal ions in the solution being greater than 1E⁻³ mol/L while the concentration of HF being less than or equal to 1E⁻² mol/L;
(2) corroding the surface of the silicon wafer by using a first chemical corrosive liquid, so as to form nanowires or porous silicon structures, the temperature being 25-90° C., and the time being 2-10 min;
the first chemical corrosive liquid being a mixed solution of HF and an oxidant, wherein the concentration of the HF is 1-15 mol/L, and the concentration of the oxidant is 0.05-0.5 mol/L;
(3) placing the silicon wafer in a second chemical corrosive liquid to perform corrective corrosion, so that the nanowires or porous silicon structures are formed into nano-deep hole structures;
the second chemical corrosive liquid being a mixed solution of an oxidant and the HF acid, the concentrations of the HF and the oxidant being respectively 0.05-0.5 mol/L and 1-10 mol/L, the reaction time being 10-1000 seconds, and the reaction temperature being 5-45° C.;
(4) placing the silicon wafer in a third chemical corrosive liquid to perform corrective corrosion, so that the nano-deep hole structures are formed into micro-structures similar to inverted pyramids;
the lower part of the micro-structure similar to the inverted pyramid being an inverted pyramidal structure, and the upper part thereof being an inverted circular truncated conical structure; the top of the micro-structure similar to the inverted pyramid being selected from one or more of a circle, an oval, or a closed figure enclosed by multiple curves;
the third chemical corrosive liquid being an alkali liquor;
the concentration of the alkali liquor being 0.001-0.1 mol/L, the reaction time being 10-1000 seconds, and the reaction temperature being 5-85° C.

5. The preparation method according to claim 4, wherein the solution containing metal ions in the step (1) further comprises HF.

6. A preparation method of a textured structure of a crystalline silicon solar cell, comprising the following steps:
(1) placing a silicon wafer into the hydrofluoric acid solution containing an oxidant and a metal salt, so as to form nanowires or porous silicon structures, the temperature being 25-90° C., and the time being 2-10 min;
the concentration of the metal ions in the solution being less than or equal to 1E⁻³ mol/L or the concentration of the metal ions in the solution being greater than 1E⁻³ mol/L while the concentration of HF being less than or equal to 1E⁻² mol/L;
(2) placing the silicon wafer in a first chemical corrosive liquid to perform corrective corrosion, so that the nanowires or porous silicon structures are formed into nano-deep hole structures;
the first chemical corrosive liquid being a mixed solution of an oxidant and the HF acid, the concentrations of the HF and the oxidant being respectively 0.05-0.5 mol/L and 1-10 mol/L, the reaction time being 10-1000 seconds, and the reaction temperature being 5-45° C.;
(3) placing the silicon wafer in a second chemical corrosive liquid to perform corrective corrosion, so that the nano-deep hole structures are formed into micro-structures similar to inverted pyramids;
the lower part of the micro-structure similar to the inverted pyramid being an inverted pyramidal structure, and the upper part thereof being an inverted circular truncated conical structure; the top of the micro-structure similar to the inverted pyramid being selected from one or more of a circle, an oval, or a closed figure enclosed by multiple curves;
the second chemical corrosive liquid being an alkali liquor;
the concentration of the alkali liquor being 0.001-0.1 mol/L, the reaction time being 10-1000 seconds, and the reaction temperature being 5-85° C.

7. A textured structure of a crystalline silicon solar cell, wherein the textured structure is mainly constructed by a plurality of pyramid micro-structures; and
the size of the pyramid is 100-500 nm.

8. The textured structure of a crystalline silicon solar cell according to claim 7, wherein the textured structure further comprises a plurality of micro-structures similar to inverted pyramids;
the lower part of the micro-structure similar to the inverted pyramid is an inverted pyramidal structure, and the upper part thereof is an inverted circular truncated conical structure; and
the top of the micro-structure similar to the inverted pyramid is selected from one or more of a circle, an oval, or a closed figure enclosed by multiple curves.

9. A preparation method of a textured structure of a crystalline silicon solar cell, comprising the following steps:
(1) immersing a silicon wafer in a solution containing metal ions, so that a layer of metal nano-particles is coated on the surface of the silicon wafer;
the concentration of the metal ions in the solution being greater than 1E⁻³ mol/L, and the concentration of HF being greater than 1E⁻² mol/L;
(2) corroding the surface of the silicon wafer by using a first chemical corrosive liquid, so as to form nanowires or porous silicon structures; the temperature being 25-90° C., and the time being 2-10 min;
the first chemical corrosive liquid being a mixed solution of HF and an oxidant, wherein the concentration of the HF is 1-15 mol/L, and the concentration of the oxidant is 0.05-0.5 mol/L;
(3) placing the silicon wafer in a second chemical corrosive liquid to perform corrective corrosion, so that the nanowires or porous silicon structures are formed into pyramid micro-structures;
the second chemical corrosive liquid being an alkali liquor;
the concentration of the alkali liquor being 0.001-0.1 mol/L, the reaction time being 10-1000 seconds, and the reaction temperature being 5-85° C.

10. The preparation method according to claim 9, wherein the solution containing metal ions in the step (1) further comprises HF.

11. A preparation method of a textured structure of a crystalline silicon solar cell, comprising the following steps:
(1) placing a silicon wafer into a hydrofluoric acid solution containing an oxidant and a metal salt, so as to form nanowires or porous silicon structures; the temperature being 25-90° C., and the time being 2-10 min;
the concentration of the metal ions in the solution being greater than 1E⁻³ mol/L, and the concentration of HF being greater than 1E⁻² mol/L;
(2) placing the silicon wafer in a first chemical corrosive liquid to perform corrective corrosion, so that the nanowires or porous silicon structures are formed into pyramid micro-structures;
the first chemical corrosive liquid being an alkali liquor;
the concentration of the alkali liquor being 0.001-0.1 mol/L, the reaction time being 10-1000 seconds, and the reaction temperature being 5-85° C.

12. The preparation method according to claim 4, wherein, before or after the correction step, the method further comprises a step of removing the metal ions, in which metal particles are removed respectively by washing the silicon wafer using a first cleaner, a second cleaner and a deionized water,
wherein the first cleaner is a nitric acid solution with mass percentage of 27-69%, the cleaning time is 60-1200 seconds, and the cleaning temperature is 5-85° C.;
the second cleaner is a hydrofluoric acid solution with mass percentage of 1-10%, the cleaning time is 60-600 seconds, and the cleaning temperature is 5-45° C.

13. The preparation method according to claim 5, wherein, before or after the correction step, the method further comprises a step of removing the metal ions, in which metal particles are removed respectively by washing the silicon wafer using a first cleaner, a second cleaner and a deionized water,
wherein the first cleaner is a nitric acid solution with mass percentage of 27-69%, the cleaning time is 60-1200 seconds, and the cleaning temperature is 5-85° C.;
the second cleaner is a hydrofluoric acid solution with mass percentage of 1-10%, the cleaning time is 60-600 seconds, and the cleaning temperature is 5-45° C.

14. The preparation method according to claim 6, wherein, before or after the correction step, the method further comprises a step of removing the metal ions, in which metal particles are removed respectively by washing the silicon wafer using a first cleaner, a second cleaner and a deionized water,
wherein the first cleaner is a nitric acid solution with mass percentage of 27-69%, the cleaning time is 60-1200 seconds, and the cleaning temperature is 5-85° C.;
the second cleaner is a hydrofluoric acid solution with mass percentage of 1-10%, the cleaning time is 60-600 seconds, and the cleaning temperature is 5-45° C.

15. The preparation method according to claim 9, wherein, before or after the correction step, the method further comprises a step of removing the metal ions, in which metal particles are removed respectively by washing the silicon wafer using a first cleaner, a second cleaner and a deionized water,
wherein the first cleaner is a nitric acid solution with mass percentage of 27-69%, the cleaning time is 60-1200 seconds, and the cleaning temperature is 5-85° C.;
the second cleaner is a hydrofluoric acid solution with mass percentage of 1-10%, the cleaning time is 60-600 seconds, and the cleaning temperature is 5-45° C.

16. The preparation method according to claim 10, wherein, before or after the correction step, the method further comprises a step of removing the metal ions, in which metal particles are removed respectively by washing the silicon wafer using a first cleaner, a second cleaner and a deionized water,
wherein the first cleaner is a nitric acid solution with mass percentage of 27-69%, the cleaning time is 60-1200 seconds, and the cleaning temperature is 5-85° C.;
the second cleaner is a hydrofluoric acid solution with mass percentage of 1-10%, the cleaning time is 60-600 seconds, and the cleaning temperature is 5-45° C.

17. The preparation method according to claim 11, wherein, before or after the correction step, the method further comprises a step of removing the metal ions, in which metal particles are removed respectively by washing the silicon wafer using a first cleaner, a second cleaner and a deionized water,
wherein the first cleaner is a nitric acid solution with mass percentage of 27-69%, the cleaning time is 60-1200 seconds, and the cleaning temperature is 5-85° C.;
the second cleaner is a hydrofluoric acid solution with mass percentage of 1-10%, the cleaning time is 60-600 seconds, and the cleaning temperature is 5-45° C.
